(19) United States
(12) Patent Application Publication
(10) Pub. No.: US 2025/0176301 A1
(43) Pub. Date: May 29, 2025

(54) SEMICONDUCTOR DEVICE INCLUDING VERTICALLY STACKED SEMICONDUCTOR ELEMENTS, METHOD OF MANUFACTURING THE SAME, AND ELECTRONIC DEVICE INCLUDING THE SAME

(71) Applicant: Samsung Electronics Co., Ltd., Suwon-si (KR)

(72) Inventors: Junyoung KWON, Suwon-si (KR); Changhyun KIM, Suwon-si (KR); Huije RYU, Suwon-si (KR); Kyung-Eun BYUN, Suwon-si (KR); Minsu SEOL, Suwon-si (KR); Eunkyu LEE, Suwon-si (KR); Changseok LEE, Suwon-si (KR)

(73) Assignee: Samsung Electronics Co., Ltd., Suwon-si (KR)

(21) Appl. No.: 18/811,177

(22) Filed: Aug. 21, 2024

(30) Foreign Application Priority Data
Nov. 28, 2023 (KR) 10-2023-0168241

(51) Int. Cl. H01L 27/146

(52) U.S. Cl. CPC H10F 39/811; H10F 39/011

(57) ABSTRACT

Provided are semiconductor devices including vertically stacked semiconductor elements, methods of manufacturing the same, and electronic devices including the same. The semiconductor device includes a first semiconductor element formed in a front-end-of-line process, a second semiconductor element formed in a back-end-of-line process, and an interlayer insulating layer provided between the first and second semiconductor elements and including an internal via structure connecting the first and second semiconductor elements to each other. The internal via structure includes a layer structure through which an upper surface of a first material layer and a lower surface of a second material layer are connected to each other. The first material layer is included in one of the first and second semiconductor elements provided below the interlayer insulating layer, and the second material layer is included in the other one of the first and second semiconductor elements that is provided above the interlayer insulating layer.

### CROSS-REFERENCE TO RELATED APPLICATION

This application is based on and claims priority under 35 U.S.C. § 119 to Korean Patent Application No. 10-2023-0168241, filed on Nov. 28, 2023, in the Korean Intellectual Property Office, the disclosure of which is incorporated by reference herein in its entirety.

### BACKGROUND

### 1. Field

The disclosure relates to interconnection structures between semiconductor elements, and more particularly, to semiconductor devices including vertically stacked semiconductor elements, methods of manufacturing the same, and electronic devices including the same.

### 2. Description of the Related Art

Silicon (Si)-based semiconductor elements may be manufactured only on wafers, and thus, high-performance computing integrated circuits may be formed only in one layer.

Recently, research has been conducted into methods of forming two-layer integrated circuits by bonding integrated circuits separately manufactured using two wafers to each other. However, due to the physical limitations of bonding technology, it is difficult to increase the integration of semiconductor elements beyond a certain level.

### SUMMARY

Provided are semiconductor devices that include vertically stacked semiconductor elements and are capable of performing high-speed operations.

Provided are semiconductor devices that include vertically stacked semiconductor elements and are capable of reducing operational power.

Provided are semiconductor devices that include vertically stacked semiconductor elements and are capable of increasing the degree of integration.

Provided are methods of manufacturing such a semiconductor devices.

Provided are electronic devices including such a semiconductor device.

Additional aspects will be set forth in part in the description which follows and, in part, will be apparent from the description, or may be learned by practice of the presented example embodiments of the disclosure.

According to an example embodiments of the disclosure, a semiconductor device including vertically stacked semiconductor elements includes a first semiconductor layer, a second semiconductor layer, and an interlayer insulating layer between the first and second semiconductor layers, the interlayer insulating layer including an internal via structure connecting the first and second semiconductor layers to each other. The internal via structure includes a layer structure through which an upper surface of a first material layer and a lower surface of a second material layer are connected to each other. The first material layer is included in one of the first and second semiconductor layers that is below the interlayer insulating layer, and the second material layer is included in the other one of the first and second semiconductor layers that is above the interlayer insulating layer.

In an example embodiment, the layer structure may include a first conductive layer in contact with the upper surface of the first material layer, a second conductive layer including an upper surface that is in contact with a first region of the lower surface of the second material layer, and a first interlayer conductive layer between the first conductive layer and the second conductive layer, the first interlayer conductive layer connecting the first and second conductive layers to each other.

In an example embodiment, the interlayer insulating layer may include a first interlayer insulating layer covering the first material layer and having the first interlayer conductive layer thereon, and a second interlayer insulating layer covering the first interlayer conductive layer and being on the first interlayer insulating layer. The first interlayer insulating layer may include a first via hole exposing the upper surface of the first material layer therethrough and covered with the first interlayer conductive layer, and the first via hole may be filled with the first conductive layer. The second interlayer insulating layer may include a second via hole exposing the first interlayer conductive layer therethrough and covered with the first region of the lower surface of the second material layer, and the second via hole may be filled with the second conductive layer.

In an example embodiment, the semiconductor device may further include a second interlayer conductive layer being apart from the first interlayer conductive layer and having a same height as the first interlayer conductive layer, and a third conductive layer between the second interlayer conductive layer and a second region of the lower surface of the second material layer. The first region and the second region may be apart from each other.

In an example embodiment, the third conductive layer may be apart from the second interlayer conductive layer.

In an example embodiment, the second material layer may include a two-dimensional channel layer.

In an example embodiment, the two-dimensional channel layer may include a source region and a drain region that are apart from each other, and a gate stack on the two-dimensional channel layer between the source region and the drain region.

In an example embodiment, the layer structure may include a conductive layer connecting a lower surface of the source region and an upper surface of the first material layer to each other.

In an example embodiment, the semiconductor device may further include a first electrode layer between the lower surface of the source region and the conductive layer and in contact with the lower surface of the source region and the conductive layer.

In an example embodiment, the first electrode layer may be wider than the conductive layer and may entirely cover an upper surface of the conductive layer.

In an example embodiment, the first electrode layer may have a width substantially equal to a width of the conductive layer and may entirely cover an upper surface of the conductive layer.

In an example embodiment, a portion of the conductive layer and the first electrode layer may be surrounded by the interlayer insulating layer.

In an example embodiment, the conductive layer may include two portions having different widths.

In an example embodiment, at least one of the first semiconductor layers or the second semiconductor layer may include a transistor.

In an example embodiment, the first semiconductor layer may include a memory, and the second semiconductor layer may include a transistor including a two-dimensional channel layer.

In an example embodiment, the two-dimensional channel layer may include one of an n-type two-dimensional semiconductor material and a p-type two-dimensional semiconductor material.

According to an example embodiment of the disclosure, there is provided a method of manufacturing a semiconductor device including vertically stacked semiconductor elements. The method includes forming a first semiconductor element on a substrate, forming a first interlayer insulating layer covering the first semiconductor element, and forming a first via hole in the first interlayer insulating layer such that a portion of the first semiconductor element is exposed through the first via hole. The method further includes filling the first via hole with a first conductive plug, forming a conductive layer on the first interlayer insulating layer to cover the first via hole and the first conductive plug, forming a second interlayer insulating layer on the first interlayer insulating layer to cover the conductive layer, forming a second via hole in the second interlayer insulating layer such that the conductive layer is exposed through the second via hole, and filling the second via hole with a second conductive plug. The method further includes forming a two-dimensional material layer on the second interlayer insulating layer to cover the second conductive plug, and forming a gate stack on a portion of the two-dimensional material layer. The second conductive plug is in contact with a lower surface of the two-dimensional material layer.

In an example embodiment, the forming of the two-dimensional material layer includes separately forming the two-dimensional material layer outside the second interlayer insulating layer, and transferring the separately-formed two-dimensional material layer onto the second interlayer insulating layer.

In an example embodiment, the method may further include forming an electrode layer between the second conductive plug and the two-dimensional material layer.

According to an example embodiment of the disclosure, there is provided an electronic device including the semiconductor device.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a cross-sectional view schematically illustrating a semiconductor device including vertically stacked semiconductor elements according to an example embodiment;

FIGS. 2 to 6 are cross-sectional views illustrating specific examples of the semiconductor device shown in FIG. 1;

FIG. 7 is a graph illustrating simulation results of a semiconductor device (e.g., bottom contact type semiconductor device) including vertically stacked semiconductor elements according to an example embodiment and a conventional top contact type semiconductor device as illustrated in FIG. 8;

FIG. 8 is a cross-sectional view illustrating a comparative sample (second sample) used in the simulation performed to obtain the results shown in FIG. 7; and

FIG. 9 is a block diagram illustrating an electronic device according to an example embodiment.

### DETAILED DESCRIPTION

Reference will now be made in detail to some example embodiments, which are illustrated in the accompanying drawings, wherein like reference numerals refer to like elements throughout. In this regard, the present example embodiments may have different forms and should not be construed as being limited to the descriptions set forth herein. Accordingly, the disclosed example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device including vertically stacked semiconductor elements, a method of manufacturing the semiconductor device, and an electronic device including the semiconductor device will be described according to some example embodiments with reference to the accompanying drawings. In the drawings, the thicknesses of layers or regions may be exaggerated for clarity of illustration.

The example embodiments described herein are for illustrative purposes only, and various modifications may be made therein. In addition, it will also be understood that when a layer is referred to as being “above” or “on” another layer or substrate, it may be directly on the other layer or substrate or be above the layer or substrate without making contact with the layer or substrate. In the drawings, like reference numerals refer to the like elements.

As used herein, singular forms may include plural forms as well unless the context clearly indicates otherwise. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary. Operations of a method are not limited to the stated order thereof.

In the disclosure, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

In addition, examples or example terms are used for the purpose of description and are not intended to limit the scope of the disclosure unless defined by the claims.

First, a semiconductor device including vertically stacked semiconductor elements is described according to an example embodiment, and a method of manufacturing the semiconductor device is also described together with the semiconductor device.

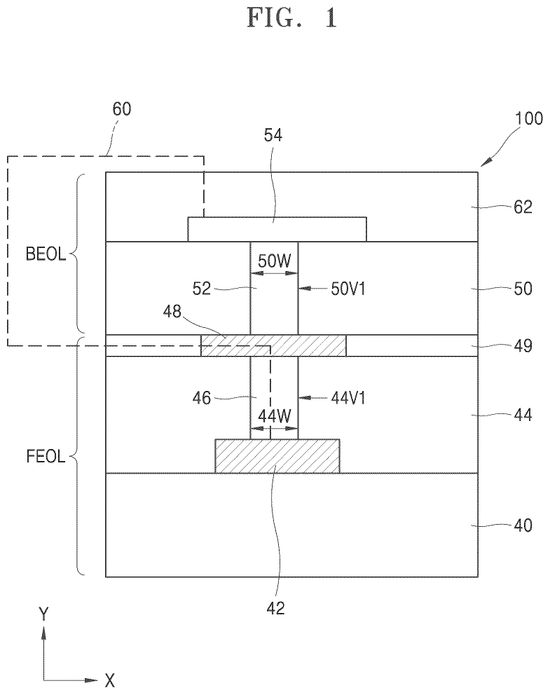

FIG. 1 schematically illustrates a semiconductor device 100 including vertically stacked semiconductor elements according to an example embodiment.

Referring to FIG. 1, the semiconductor device 100 includes a portion formed in a front-end-of-line (FEOL) process and a portion formed in a back-end-of-line (BEOL) process. The FEOL process may also be referred to as a leading edge process. The semiconductor device 100 may include a first semiconductor element 42 and a second semiconductor element 54 that are vertically stacked. The first semiconductor element 42 is formed on a substrate 40 in the FEOL process, and the second semiconductor element 54 is formed in the BEOL process. On the other hand, the second semiconductor element 54 may be a semiconductor element that may be formed in the FEOL process but that is not formed in the FEOL process in terms of performance (function) or position. In an example, the first semiconductor element 42 may be referred to as a semiconductor layer including the first semiconductor element 42 or on which the first semiconductor element 42 is formed, and the second semiconductor element 54 may be referred to as a semiconductor layer including the second semiconductor element 54 or on which the second semiconductor element 54 is formed.

In an example, the first semiconductor element 42 and the second semiconductor element 54 may be of the same type or different types. For example, both of the first and second semiconductor elements 42 and 54 may be or include transistors. In an example, the transistors may include, but are not limited to, field effect transistors (FETs) or thin film transistor (TFTs). In an example, the second semiconductor element 54 may include a switching transistor or a power transistor. In an example, the first semiconductor element 42 may be a memory device or one of semiconductor elements that form a circuit (e.g., a logic circuit). In an example, the first semiconductor element 42 may represent an entire circuit formed on the substrate 40 in the FEOL process.

For example, the substrate 40 may be a substrate including a semiconductor material, such as a silicon substrate. However, the substrate 40 is not limited thereto. In an example, the substrate 40 may be a circuit board, and the first semiconductor element 42 may be one of semiconductor elements formed on the circuit board. The first semiconductor element 42 may be covered with a first interlayer insulating layer 44. In an example, the first interlayer insulating layer 44 may include, but is not limited to, a silicon oxide (e.g., SiO₂). In an example, the first interlayer insulating layer 44 may be formed by various deposition methods such as a chemical vapor deposition (CVD) method, a physical vapor deposition (PVD) method, a sputtering method, or an atomic layer deposition (ALD) method. Therefore, the first interlayer insulating layer 44 may include a dielectric material other than silicon oxides as long as it is possible to deposit the dielectric material by the deposition methods stated above. An upper surface of the first interlayer insulating layer 44 may be made flat through a planarization process. A first via hole 44V1 is formed in the first interlayer insulating layer 44. The first via hole 44V1 may be formed on the first semiconductor element 42. The first semiconductor element 42 is exposed through the first via hole 44V1. In an example, a portion of the first semiconductor element 42 may be exposed through the first via hole 44V1. For example, when the first semiconductor element 42 is a transistor included in a logic circuit, a source or drain region of the transistor may be exposed through the first via hole 44V1. The first via hole 44V1 may be filled with a first conductive plug 46, and the first conductive plug 46 may be in contact with the first semiconductor element 42. In an example, the first via hole 44V1 may be completely filled with the first conductive plug 46. The first conductive plug 46 is a conductive material layer and may thus be referred to as a first conductive layer. In an example, the first conductive plug 46 may include various conductive materials that may be used to connect vertically stacked semiconductor elements to each other. For example, the first conductive plug 46 may include the same material as a first conductive layer 48 formed on the first conductive plug 46. However, the first conductive plug 46 is not limited thereto. For example, the first conductive plug 46 may include a single metal, an alloy, or a conductive compound.

The first conductive layer 48 covering the first conductive plug 46 is formed on the first interlayer insulating layer 44. In an example, the first conductive layer 48 may be a wire that electrically connects separate semiconductor elements to each other. In an example, the first conductive layer 48 may be a conductive pad layer for securing a contact margin. In an example, the first conductive layer 48 may include gold (Au), silver (Ag), copper (Cu), or aluminum (Al). However, the first conductive layer 48 is not limited thereto. The first conductive layer 48 may include an alloy or a compound containing a conductive element. In an example, the first conductive layer 48 may be the same material layer as the first conductive plug 46. In this case, the first conductive plug 46 and the first conductive layer 48 may form a single continuous material layer, and the first conductive plug 46 and the first conductive layer 48 may be formed through a single stacking process. A second interlayer insulating layer 49 may cover the first interlayer insulating layer 44 around the first conductive layer 48. In an example, the height of the second interlayer insulating layer 49 may be substantially the same as the height of the first conductive layer 48. In an example, the second interlayer insulating layer 49 may include the same material as the first interlayer insulating layer 44, or may include a material that is different from a material included in the first interlayer insulating layer 44. In an example, the second interlayer insulating layer 49 may be formed by any of the various deposition methods that may be used to form the first interlayer insulating layer 44. A third interlayer insulating layer 50 may be provided on the second interlayer insulating layer 49 to cover the first conductive layer 48. The third interlayer insulating layer 50 may be thicker than the second interlayer insulating layer 49 and the first conductive layer 48. In an example, the third interlayer insulating layer 50 may be formed in the BEOL process. In an example, the first conductive layer 48 and the second interlayer insulating layer 49 may also be formed in the BEOL process. In an example, the third interlayer insulating layer 50 may be a dielectric layer including a dielectric material. In an example, the third interlayer insulating layer 50 may include an oxide or nitride. For example, the third interlayer insulating layer 50 may be a silicon oxide layer. However, the third interlayer insulating layer 50 is not limited thereto. In an example, the third interlayer insulating layer 50 may also be formed by the various deposition methods that may be used to form the first interlayer insulating layer 44. In an example, material of the first and second interlayer insulating layers 44 and 49 may be the same as or different from that of the third interlayer insulating layer 50.

When the second and third interlayer insulating layers 49 and 50 include the same dielectric material, the second and third interlayer insulating layers 49 and 50 may form a single interlayer insulating layer. That is, a single interlayer insulating layer 49+50 covering the first conductive layer 48 may be on the first interlayer insulating layer 44. An upper surface of the third interlayer insulating layer 50 may be flat. A second via hole 50V1 may be formed through the third interlayer insulating layer 50. The second via hole 50V1 may be positioned on the first conductive layer 48 between both edges of the first conductive layer 48. The first conductive layer 48 may be exposed through the second via hole 50V1. The second via hole 50V1 is filled with a second conductive plug 52. The second conductive plug 52 may be in direct contact with the first conductive layer 48. In an example, the second conductive plug 52 may include an electrically conductive material. In an example, the second conductive plug 52 may include the same material as the first conductive plug 46, or may include a material that is different from a material included in the first conductive plug 46. In an example, the second via hole 50V1 may be located above the first via hole 44V1. At least a portion of the second via hole 50V1 and at least a portion of the first via hole 44V1 may overlap each other. In an example, the first and second via holes 44V1 and 50V1 may substantially and completely overlap each other. For example, the center of the second via hole 50V1 may overlap with the center of the first via hole 44V1. The centers of the first and second via holes 44V1 and 50V1 may be on a vertical line passing through the first and second via holes 44V1 and 50V1 vertically. For example, in a horizontal direction (for example, X-axis direction), a width 50W of the second via hole 50V1 may be substantially the same as a width 44W of the first via hole 44V1, or the width 50W of the second via hole 50V1 may be different from the width 44W of the first via hole 44V1. For example, the width 50W of the second via hole 50V1 may be greater than or less than the width 44W of the first via hole 44V1. In an example, the first conductive plug 46 and the second conductive plug 52 may have the same layer structure or different layer structures from each other. For example, each of the first and second conductive plugs 46 and 52 may have a single-layer structure or a multilayer structure (e.g., a structure in which two different conductive layers are stacked). In another example, one of the first and second conductive plugs 46 and 52 may have a single layer structure, and the other may have a multilayer structure.

The second semiconductor element 54 that covers the second via hole 50V1 and contacts the second conductive plug 52 is provided on the third interlayer insulating layer 50. In an example, the second semiconductor element 54 may completely cover the second via hole 50V1 and may be in contact with the entire upper surface of the second conductive plug 52. In an example, the second semiconductor element 54 may include, but is not limited to, a semiconductor component such as a transistor. In an example, the second semiconductor element 54 may include a circuit layer (or a semiconductor circuit) that includes some or all of components such as transistors, capacitors, diodes, resistors, optical components, or sensors used for operations of a semiconductor device. In an example, various types of transistors may be formed in the FEOL process. However, some of the transistors may not necessarily be formed in the FEOL process in terms of functionality. Some semiconductor components other than transistors may not necessarily be formed in the FEOL process.

The second semiconductor element 54 may include semiconductor components or electronic components that may be formed in the FEOL process but may not necessarily be formed in the FEOL process. For example, the second semiconductor element 54 may include a transistor such as a switching transistor or a power transistor that may be formed in the FEOL process. Components that may be formed in the FEOL process but are not formed in the FEOL process may be formed in the BEOL process, and thus, more semiconductor components or electronic components having high functionality may be formed on the substrate 40 in the FEOL process. In other words, it may be possible to increase the degree of integration of highly functional semiconductor elements formed on the substrate 40 in the FEOL process.

In an example, when the second semiconductor element 54 includes a transistor, the transistor may have a source or drain region (electrode) located on the second conductive plug 52 and a lower surface of the source or drain region may be in direct contact with the second conductive plug 52. In other words, the second conductive plug 52 may be provided under the source or drain region of the transistor of the second semiconductor element 54. Owing to the arrangement of the first and second via holes 44V1 and 50V1 and the arrangement of the second semiconductor element 54 and the second conductive plug 52, the second semiconductor element 54 and the first semiconductor element 42 may be directly connected to each other in a vertical direction through the first and second conductive plugs 46 and 52. Because the first semiconductor element 42 formed in the FEOL process and the second semiconductor element 54 formed in the BEOL process are not connected to each other through a detouring path as shown by a dashed line 60 but are directly connected to each other through a vertical path, an electrical signal transmission path between the first semiconductor element 42 and the second semiconductor element 54 may be short. Therefore, electrical resistance between the first semiconductor element 42 and the second semiconductor element 54 may be low, and resistance capacitance (RC) delay (e.g., RC time constant) may also be reduced. The rate of signal transmission may be improved, and the operational power of the semiconductor device 100 may also be lowered. In addition, because the first semiconductor element 42 and the second semiconductor element 54 are directly connected to each other in the vertical direction, the horizontal size of the semiconductor device 100 may be reduced and the degree of integration of the semiconductor device 100 may be increased.

A fourth interlayer insulating layer 62 covering the second semiconductor element 54 may be provided on the third interlayer insulating layer 50. In an example, the fourth interlayer insulating layer 62 may be a protective layer. In an example, the fourth interlayer insulating layer 62 may be formed by a deposition method used to form the third interlayer insulating layer 50. The fourth interlayer insulating layer 62 may include the same material as the third interlayer insulating layer 50, or may include a material that is different from a material included in the third interlayer insulating layer 50.

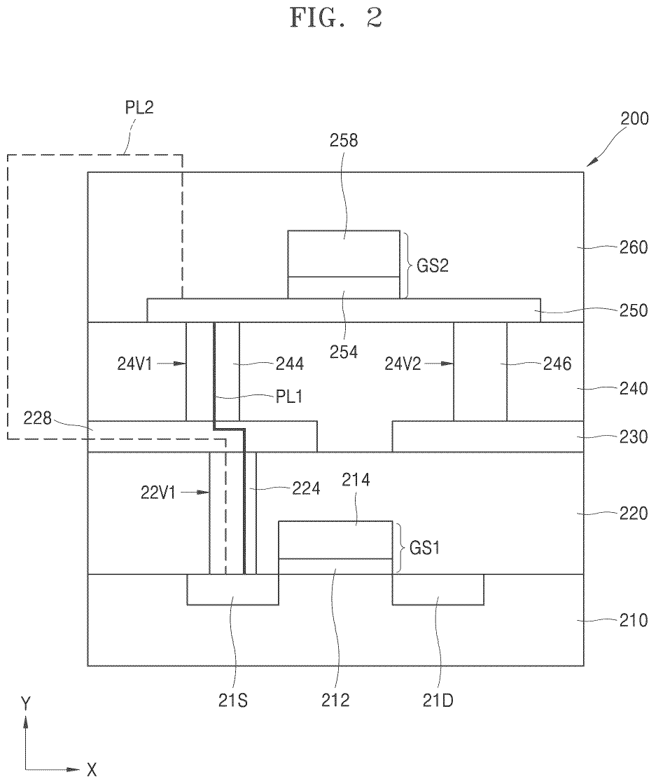

FIG. 2 illustrates a first semiconductor device 200 as an example of the semiconductor device 100 described with reference to FIG. 1.

Referring to FIG. 2, first and second doped layers 21S and 21D are formed apart from each other in a first substrate 210 of the first semiconductor device 200. In an example, the first substrate 210 may be a semiconductor substrate, but is not limited thereto. In an example, the first substrate 210 may be a silicon-containing substrate or a silicon substrate, but is not limited thereto. In an example, the first substrate 210 may include a silicon substrate doped with an n-type or p-type dopant. In an example, the n-type dopant may be a material used for doping a semiconductor substrate and may include a pentavalent element or a Group V element. For example, the n-type dopant may include phosphorus (P), antimony (Sb), gallium (Ga), beryllium (Be), or zinc (Zn), but is not limited thereto.

The p-type dopant may be a material used for doping a semiconductor substrate and may include a trivalent element or a Group Ill element. For example, the p-type dopant may include boron (B). The first and second doped layers 21S and 21D may be regions doped with a material of the opposite type to that of a material with which the first substrate 210 is doped.

In an example, the first and second doped layers 21S and 21D may be n-type doped regions formed by doping the first substrate 210 with an n-type dopant, or p-type doped regions formed by doping the first substrate 210 with a p-type dopant. A first gate stack GS1 is provided on the first substrate 210 between the first doped layer 21S and the second doped layer 21D. One of the first and second doped layers 21S and 21D may be a source region, and the other may be a drain region. The first and second doped layers 21S and 21D may be in contact with the first gate stack GS1. The first substrate 210 between the first and second doped layers 21S and 21D and below the first gate stack GS1 may be a channel region. The channel region may be referred to as a channel layer. The first gate stack GS1 may include, but is not limited to, a first gate insulating layer 212 and a first gate electrode 214 that are sequentially stacked. The first gate electrode 214 is apart from the first and second doped layers 21S and 21D.

In an example, the first gate electrode 214 may be formed by various deposition methods (e.g., CVD, PVD, sputtering, ALD, or the like), and any electrode material (e.g., metal, conductor, an alloy, or the like) that may be deposited by such deposition methods may be used to form the first gate electrode 214.

The first and second doped layers 21S and 21D and the first gate stack GS1 may form a first transistor. The first transistor may be a high-performance transistor formed in an FEOL process. The first transistor may correspond to or constitute the first semiconductor element 42 described with reference to FIG. 1. In an example, the first substrate 210 may be provided with a plurality of first transistors. A lower interlayer insulating layer 220 may be formed on the first substrate 210 to cover the first and second doped layers 21S and 21D and the first gate stack GS1. The lower interlayer insulating layer 220 may correspond to the first interlayer insulating layer 44 described with reference to FIG. 1. Therefore, the lower interlayer insulating layer 220 may include material that is the same as or different from that of the first interlayer insulating layer 44 described with reference to FIG. 1. An upper surface of the lower interlayer insulating layer 220 may be flat. A third via hole 22V1 is formed through the lower interlayer insulating layer 220. The third via hole 22V1 may be located on the first doped layer 21S and apart from the first gate stack GS1. The first doped layer 21S may be exposed through the third via hole 22V1. The third via hole 22V1 may correspond to the first via hole 44V1 described with reference to FIG. 1. The third via hole 22V1 may be filled with a third conductive plug 224, and the third conductive plug 224 may be in contact with the first doped layer 21S. The third conductive plug 224 may correspond to the first conductive plug 46 described with reference to FIG. 1. Therefore, a material of the third conductive plug 224 may be the same as or different from a material included in the first conductive plug 46. The third conductive plug 224 may completely fill the third via hole 22V1, and the height of an upper surface of the third conductive plug 224 may be the same as the height of the upper surface of the lower interlayer insulating layer 220. Second and third conductive layers 228 and 230 are formed apart from each other on the lower interlayer insulating layer 220. Each of the second and third conductive layers 228 and 230 may correspond to the first conductive layer 48 described with reference to FIG. 1. In an example, the second and third conductive layers 228 and 230 may include the same conductive material, or different conductive materials from each other. In an example, the second and third conductive layers 228 and 230 may be used as conductive pads. In an example, the second conductive layer 228 and/or the third conductive layer 230 may be a wiring layer connected to another semiconductor element (not shown).

In an example, the second and third conductive layers 228 and 230 may include a material that is the same as or different from a material included in the first conductive layer 48 of FIG. 1. The second conductive layer 228 may be located above the first doped layer 21S and the third via hole 22V1, and the third conductive layer 230 may be located above the second doped layer 21D. The second conductive layer 228 may completely cover the third via hole 22V1.

In an example, the FEOL process may be from the forming of the first transistor to the forming of the lower interlayer insulating layer 220. However, the second and third conductive layers 228 and 230 may also be formed in the FEOL process. In another example, the forming of the second and third conductive layers 228 and 230 may be included in a BEOL process instead of in the FEOL process.

An intermediate interlayer insulating layer 240 covering the second and third conductive layers 228 and 230 is formed on the lower interlayer insulating layer 220. The intermediate interlayer insulating layer 240 may correspond to the third interlayer insulating layer 50 described with reference to FIG. 1. An upper surface of the intermediate interlayer insulating layer 240 may be flat. The intermediate interlayer insulating layer 240 may include a material that is the same as or different from a material included in the lower interlayer insulating layer 220. In an example, the intermediate interlayer insulating layer 240 may include a material that may easily adhere to a channel layer 250. The intermediate interlayer insulating layer 240 includes fourth and fifth via holes 24V1 and 24V2 that are apart from each other. The fourth via hole 24V1 may be located on the second conductive layer 228, and the fifth via hole 24V2 may be located on the third conductive layer 230. In an example, the fourth via hole 24V1 may be positioned directly above the third via hole 22V1 in a vertical direction. For example, the fourth via hole 24V1 and the third via hole 22V1 may be on the same vertical line. In an example, the fourth via hole 24V1 may be located on the second conductive layer 228 but may not be located directly above the third via hole 22V1. For example, the fourth via hole 24V1 may be apart from the third via hole 22V1 in a horizontal direction. In other words, the fourth via hole 24V1 may be located on the second conductive layer 228 but may not vertically overlap the third via hole 22V1 (e.g., may be partially offset from the third via hole 22V1 in a vertical direction). In an example, the width of the fourth via hole 24V1 may be substantially the same as or different from the width of the third via hole 22V1. In an example, the widths of the fourth and fifth via holes 24V1 and 24V2 may be substantially the same or different. The fourth via hole 24V1 is filled with a fourth conductive plug 244, and the fifth via hole 24V2 is filled with a fifth conductive plug 246. In an example, the fourth and fifth conductive plugs 244 and 246 may include the same material or different materials from each other. In an example, the fourth and fifth conductive plugs 244 and 246 may include a material that is the same as or different from a material included in the third conductive plug 224. The fourth conductive plug 244 may completely fill the fourth via hole 24V1 and may be in contact with the second conductive layer 228. The fifth conductive plug 246 may completely fill the fifth via hole 24V2 and may be in contact with the third conductive layer 230. In an example, the second conductive layer 228 may be provided between the third and fourth conductive plugs 224 and 244 that are vertically arranged conductive layers and may connect the third and fourth conductive plugs 224 and 244 to each other. Therefore, the second conductive layer 228 may be referred to as an interlayer conductive layer.

The heights of upper surfaces of the fourth and fifth conductive plugs 244 and 246 may be equal to each other, and may be equal to the height of an upper surface of the intermediate interlayer insulating layer 240.

The channel layer 250 is provided on the intermediate interlayer insulating layer 240. The channel layer 250 may cover the fourth and fifth via holes 24V1 and 24V2 and may be in contact with the fourth and fifth conductive plugs 244 and 246. The channel layer 250 may cover the entire upper surfaces of the fourth and fifth conductive plugs 244 and 246. Thus, the upper surfaces of the fourth and fifth conductive plugs 244 and 246 may be in contact with a lower surface of the channel layer 250. In an example, the channel layer 250 may be or include a conductive two-dimensional (2D) material layer. In an example, the intermediate interlayer insulating layer 240 may include a material layer that is suitable for attaching a 2D material layer thereto or forming a 2D material layer thereon. For example, the intermediate interlayer insulating layer 240 may include hafnium oxide, but is not limited thereto.

In an example, the channel layer 250 may be formed elsewhere or separately and may then be transferred onto the intermediate interlayer insulating layer 240 to cover the fourth and fifth conductive plugs 244 and 246. In an example, when the channel layer 250 is transferred onto the intermediate interlayer insulating layer 240, the transfer process may be performed at a temperature lower than about 200° C. (e.g., at a temperature of about 150° C. or less). However, the temperature is not limited thereto.

In an example, the channel layer 250 may be formed directly on the intermediate interlayer insulating layer 240 to cover the fourth and fifth conductive plugs 244 and 246. For example, the channel layer 250 may be formed directly on the fourth and fifth conductive plugs 244 and 246 and the intermediate interlayer insulating layer 240 through a low-temperature process. For example, the channel layer 250 may be grown by a growth method using a low-temperature CVD process. In an example, the low-temperature CVD process may be performed at a temperature of about 350° C. or less.

As described above, the channel layer 250 may be formed through a transfer process or a low-temperature process. Thus, transistors may be formed in the BEOL process above semiconductor elements formed in the FEOL process without affecting the semiconductor elements formed in the FEOL process.

In an example, the channel layer 250 may be a 2D material layer, and the fourth and fifth conductive plugs 244 and 246 may be material layers that easily adhere to the 2D material layer. For example, the 2D material layer may include an n-type 2D semiconductor material or a p-type 2D semiconductor material. In an example, the n-type 2D semiconductor material may include at least one of MoS₂, MoSe₂, MoTe₂, and WS₂, but is not limited thereto. In an example, the p-type 2D semiconductor material may include at least one of WSe₂, MoTe₂, and PtSe₂, but is not limited thereto.

A portion of the channel layer 250 that is in contact with the fourth conductive plug 244 may be a source region, and a portion of the channel layer 250 that is in contact with the fifth conductive plug 246 may be a drain region. The opposite may also be possible. In an example, the fourth conductive plug 244 that is in direct contact with the source region of the channel layer 250 may be referred to as a source electrode or a source electrode layer. In addition, the fifth conductive plug 246 that is in direct contact with the drain region of the channel layer 250 may be referred to as a drain electrode or a drain electrode layer. One of the source electrode (layer) and the drain electrode (layer) may be referred to as a first electrode (layer), and the other may be referred to as a second electrode (layer).

The channel layer 250 may cover the upper surfaces of the fourth and fifth conductive plugs 244 and 246 and may be vertically connected to the first transistor through the fourth conductive plug 244, the second conductive layer 228, and the third conductive plug 224. That is, the channel layer 250 may be connected to the first doped layer 21S of the first transistor in a vertically downward direction through the fourth conductive plug 244, the second conductive layer 228, and the third conductive plug 224. Reference number PL1 indicates the vertical downward connection (vertical downward path). A dashed line PL2 indicates another path (existing path or conventional path) through which the channel layer 250 and the first doped layer 21S of the first transistor may be electrically connected to each other. Comparing the path PL2 with the vertical downward path PL1, the vertical downward path PL1 is much shorter than the existing path PL2. Therefore, electrical resistance between the channel layer 250 and the first doped layer 21S of the first transistor may be much lower when the vertical downward path PL1 is used than when the existing path PL2 is used. RC delay may be markedly reduced when the vertical downward path PL1 is used. Therefore, the transmission rate of electrical signals may be higher when the vertical downward path PL1 is used than when the existing path PL2 is used. In addition, the number of layers and the number of processes involved in the forming of the vertical downward path PL1 are less than the number of layers and the number of processes involved in the forming of the existing path PL2. Therefore, compared to the related art, processes and circuits may be simplified by using the vertical downward path PL1.

A second gate stack GS2 is provided on the channel layer 250. The second gate stack GS2 may be located between the fourth conductive plug 244 and the fifth conductive plug 246. In an example, the second gate stack GS2 may be horizontally apart from the fourth and fifth conductive plugs 244 and 246. In an example, the second gate stack GS2 may include a second gate insulating layer 254 and a second gate electrode 258 that are sequentially stacked. In an example, the second gate insulating layer 254 may include a material that is the same as or different from a material included in the first gate insulating layer 212. In an example, the second gate electrode 258 may include a material that is the same as or different from a material included in the first gage electrode 214. The channel layer 250 and the second gate stack GS2 may form a second transistor. When expanding the range of the second transistor, the fourth and fifth conductive plugs 244 and 246 may be included in the expanded second transistor.

As described above, the channel layer 250 is vertically and downwardly connected to the first doped layer 21S of the first transistor through the fourth conductive plug 244, the second conductive layer 228, and the third conductive plug 224. This means that the second transistor is connected to the first transistor in a vertical downward direction. In addition, because the second transistor is formed through the BEOL process, it may be stated that a transistor formed in the BEOL process is connected to a transistor formed in the FEOL process in a vertical downward direction. In addition, it may be stated that an interconnection structure, an interconnection layer structure, a layer structure, a stacked structure, or a via structure is provided between a transistor formed in the FEOL process and a transistor formed in the BEOL process to vertically connect the two transistors. As shown in FIG. 2, the third and fourth via holes 22V1 and 24V1 that are provided vertically between the first and second transistors may correspond to the via structure. Because the third and fourth via holes 22V1 and 24V1 are formed between the vertically stacked first and second transistors, the via structure may be referred to as an internal via structure.

Because the first and second transistors may be electrically connected to each other through the vertical downward path PL1 instead of the existing path PL2, the first semiconductor device 200 does not need a space or volume for the existing path PL2. Thus, the size of the first semiconductor device 200 may be reduced compared to the case in which the first and second transistors are connected to each other through the existing path PL2. Thus, the degree of integration of the first semiconductor device 200 may be increased, and the degree of integration of an upper-level semiconductor device including the first semiconductor device 200 may be increased.

An upper interlayer insulating layer 260 covering the channel layer 250 and the second gate stack GS2 is formed on the intermediate interlayer insulating layer 240. The upper interlayer insulating layer 260 may correspond to the fourth interlayer insulating layer 62 described with reference to FIG. 1. In an example, an upper surface of the upper interlayer insulating layer 260 may be flat. In an example, the upper interlayer insulating layer 260 may be a protective layer. In an example, the upper interlayer insulating layer 260 may include a material that is the same as or different from a material included in the lower interlayer insulating layer 220.

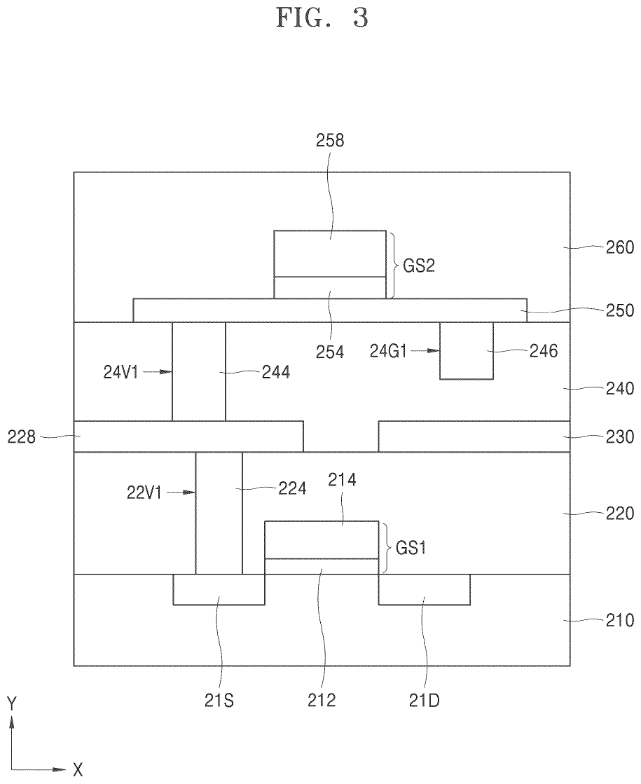

In an example, the fifth conductive plug 246 and the third conductive layer 230 of the first semiconductor device 200 may not be in contact with each other but may be apart from each other, as shown in FIG. 3.

For example, referring to FIG. 3, the intermediate interlayer insulating layer 240 may include the fourth via hole 24V1 and a first groove 24G1. The first groove 24G1 is located above the third conductive layer 230 and is apart from the third conductive layer 230. The first groove 24G1 is completely filled with the fifth conductive plug 246.

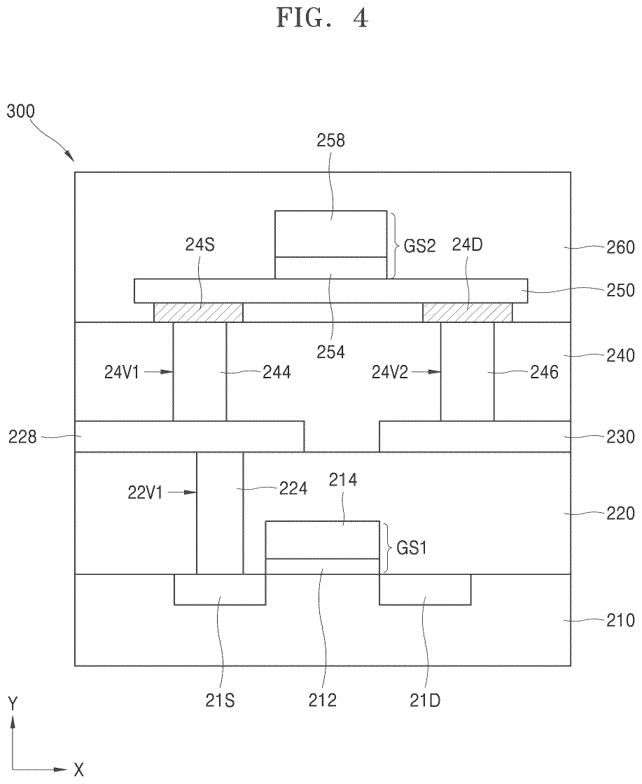

FIG. 4 illustrates a second semiconductor device 300 as an example of the semiconductor device 100 described with reference to FIG. 1. Only the difference from the first semiconductor device 200 of FIG. 2 is described.

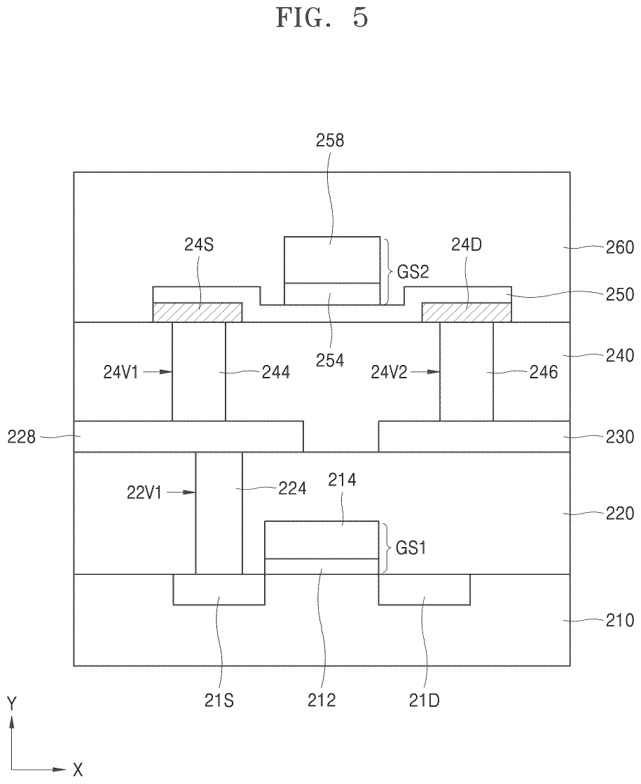

Referring to FIG. 4, a first electrode layer 24S is provided between a fourth conductive plug 244 and a channel layer 250, and a second electrode layer 24D is provided between a fifth conductive plug 246 and the channel layer 250. In an example, the first electrode layer 24S may be a source electrode and the second electrode layer 24D may be a drain electrode. The first electrode layer 24S may be in direct contact with the channel layer 250 and the fourth conductive plug 244 and may cover the entire upper surface of the fourth conductive plug 244. The second electrode layer 24D may be in direct contact with the channel layer 250 and the fifth conductive plug 246 and may cover the entire upper surface of the fifth conductive plug 246. As the first and second electrode layers 24S and 24D are provided, the channel layer 250 may be apart from an intermediate interlayer insulating layer 240. However, as shown in FIG. 5, the channel layer 250 may cover the first and second electrode layers 24S and 24D and may be in contact with an upper surface of the intermediate interlayer insulating layer 240 between the first electrode layer 24S and the second electrode layer 24D. In FIGS. 4 and 5, the channel layer 250 may be formed by a transfer method or a direct forming method. In an example, each of the first and second electrode layers 24S and 24D may include a conductive material layer that may easily adhere to the channel layer 250 without changing the material properties of the channel layer 250. For example, each of the first and second electrode layers 24S and 24D may include a conductive material layer on which the channel layer 250 may be easily formed. In an example, each of the first and second electrode layers 24S and 24D may include a conductive material layer on which the channel layer 250 may be easily deposited without changing or significantly changing in the initial material properties of the channel layer 250. In an example, the first and second electrode layers 24S and 24D may include a material that may be used as a source or drain electrode of a FET.

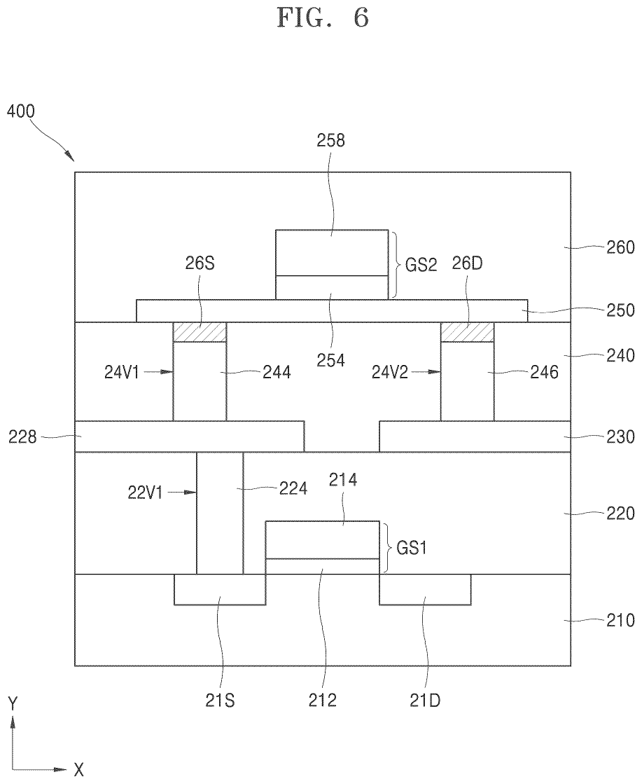

FIG. 6 illustrates a third semiconductor device 400 as an example of the semiconductor device 100 described with reference to FIG. 1. Only the difference from the first semiconductor device 200 of FIG. 2 is described.

Referring to FIG. 6, a third electrode layer 26S is provided between a fourth conductive plug 244 and a channel layer 250, and a fourth electrode layer 26D is provided between a fifth conductive plug 246 and the channel layer 250.

The third electrode layer 26S may be in direct contact with the channel layer 250 and the fourth conductive plug 244 and may cover the entire upper surface of the fourth conductive plug 244. The fourth electrode layer 26D may be in direct contact with the channel layer 250 and the fifth conductive plug 246 and may cover the entire upper surface of the fifth conductive plug 246. A fourth via hole 24V1 is filled by sequentially stacking the fourth conductive plug 244 and the third electrode layer 26S. For example, most of the fourth via hole 24V1 (e.g., about ½ or more of the total volume of the fourth via hole 24V1) may be filled with the fourth conductive plug 244, and the rest of the fourth via hole 24V1 may be filled with the third electrode layer 26S. The height of an upper surface of the third electrode layer 26S may be substantially the same as the height of an upper surface of an intermediate interlayer insulating layer 240 around the fourth via hole 24V1. A fifth via hole 24V2 is filled by sequentially stacking the fifth conductive plug 246 and the fourth electrode layer 26D. For example, most of the fifth via hole 24V2 (e.g., about ½ or more of the total volume of the fifth via hole 24V2) may be filled with the fifth conductive plug 246, and the rest of the fifth via hole 24V2 may be filled with the fourth electrode layer 26D. The height of an upper surface of the fourth electrode layer 26D may be substantially the same as the height of an upper surface of the intermediate interlayer insulating layer 240 around the fifth via hole 24V2. In an example, the thickness of the third electrode layer 26S is less than the thickness of the fourth conductive plug 244, and the thickness of the fourth electrode layer 26D is less than the thickness of the fifth conductive plug 246. In an example, the third and fourth electrode layers 26S and 26D may include the same material or different materials. In an example, the third and fourth electrode layers 26S and 26D may include a material that is the same as or different from a material included in the first and second electrode layers 24S and 24D of the second semiconductor device 300.

In an example, the fifth via hole 24V2 shown in FIGS. 5 and 6 may be replaced with the first groove 24G1 described with reference to FIG. 3. In this case, material layers filling the first groove 24G1 may be the same as those shown in FIGS. 5 and 6.

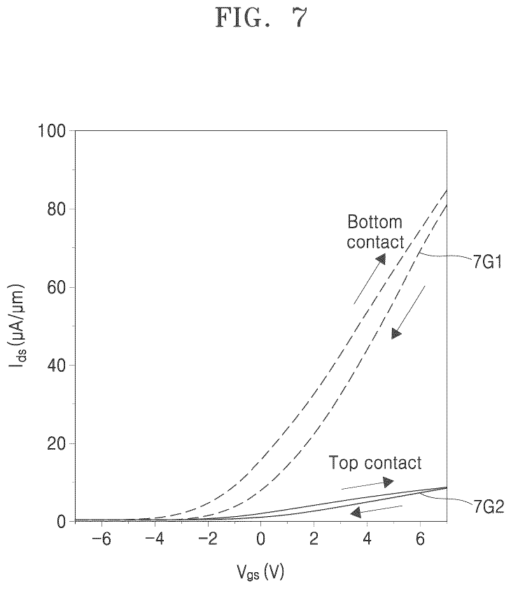

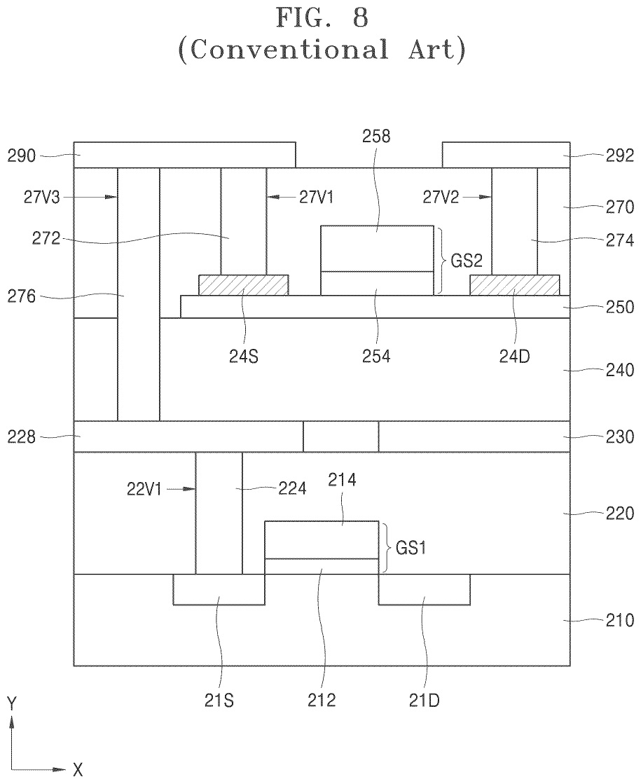

FIG. 7 illustrates results of a simulation performed to confirm electrical characteristics (e.g., current-voltage characteristics) of a semiconductor device (e.g., bottom contact type semiconductor device) including vertically stacked semiconductor elements according to an example embodiment and a conventional top contact type semiconductor device as illustrated in FIG. 8.

In the simulation through which the results shown in FIG. 7 are obtained, a first sample and a second sample were used. The first sample corresponds to a semiconductor device including vertically stacked semiconductor elements according to an example embodiment. As in the second semiconductor device 300 described with reference to FIG. 4 or 5, in the first sample, a transistor formed in an FEOL process and a transistor formed in a BEOL process are vertically connected to each other through an internal via structure. The second sample is for comparison with the first sample and corresponds to an existing semiconductor device. FIG. 8 illustrates the second sample. Only the difference from the first sample is described.

Referring to FIG. 8, a first electrode layer 24S and a second electrode layer 24D are formed on an upper surface of a channel layer 250 at both sides of a second gate stack GS2, respectively. The channel layer 250, the first and second electrode layers 24S and 24D, and the second gate stack GS2 are covered with an upper interlayer insulating layer 270, and an upper surface of the upper interlayer insulating layer 270 is flat. The upper interlayer insulating layer 270 includes a sixth via hole 27V1 through which the first electrode layer 24S is exposed and a seventh via hole 27V2 through which the second electrode layer 24D is exposed. The sixth via hole 27V1 is filled with a sixth conductive plug 272, and the seventh via hole 27V2 is filled with a seventh conductive plug 274. The heights of upper surfaces of the sixth and seventh conductive plugs 272 and 274 may be the same as the height of an upper surface of the upper interlayer insulating layer 270. The upper interlayer insulating layer 270 may also include an eighth via hole 27V3. The eighth via hole 23V3 penetrates the upper interlayer insulating layer 270 and the intermediate interlayer insulating layer 240. Therefore, a second conductive layer 228 is exposed through the eighth via hole 27V3. The eighth via hole 27V3 is filled with an eighth conductive plug 276. The height of an upper surface of the eighth conductive plug 276 may be the same as the height of the upper surface of the upper interlayer insulating layer 270. A fourth conductive layer 290 and a fifth conductive layer 292 are formed on the upper interlayer insulating layer 270. The fourth conductive layer 290 connects the sixth conductive plug 272 and the eighth conductive plug 276 to each other, and the fifth conductive layer 292 covers the seventh conductive plug 274. In the second sample, a transistor formed in a BEOL process is not connected to a transistor formed in an FEOL process in a vertical downward direction. In the second sample, the transistor formed in the BEOL process is connected to the transistor formed in the FEOL process sequentially through the sixth conductive plug 272, the fourth conductive layer 290, the eighth conductive plug 276, the second conductive layer 228, and a third conductive plug 224.

The simulation was performed at room temperature, and in each of the first and second samples, a channel layer was a MoS₂ layer, a gate insulating layer was an Al₂O₃ layer, and an interlayer insulating layer formed in contact with the channel layer was an HfO₂ layer.

Referring again to FIG. 7, a first curve 7G1 shows current-voltage characteristics of the first sample (bottom contact type) in which a source electrode and a drain electrode are provided below a channel layer and are in contact with a lower surface of the channel layer. A second curve 7G2 shows current-voltage characteristics of the second sample (top contact type) in which a source electrode and a drain electrode are provided on a channel layer and are in contact with an upper surface of the channel layer. In FIG. 7, the horizontal axis refers to a voltage applied between a gate and a source and the vertical axis refers to a current between the source and a drain.

Comparing the first and second curves 7G1 and 7G2 shown in FIG. 7, current increases as the applied voltage increases in each of the first and second samples. However, current increases much more in the first sample (refer to the first curve 7G1) than in the second sample (refer to the second curve 7G2). The current in the first sample is about 10 times the current in the second sample.

The first and second samples differ only in the method of connecting a transistor formed in an FEOL process to a transistor formed in a BEOL process, and the two transistors have the same basic structure. Considering this, the results shown in FIG. 7 indicate that contact resistance between two transistors is lower when the two transistors are connected to each other through an internal via structure than when the two transistors are connected to each other by a method of the related art. That is, the results shown in FIG. 7 indicate that the operational power of two transistors or a device including two transistors may be reduced by connecting the two transistors through an internal via structure.

The above-described semiconductor devices each including vertically stacked semiconductor elements may be applied to TFT circuit structures such as TFT circuit structures of displays, and various other electronic devices.

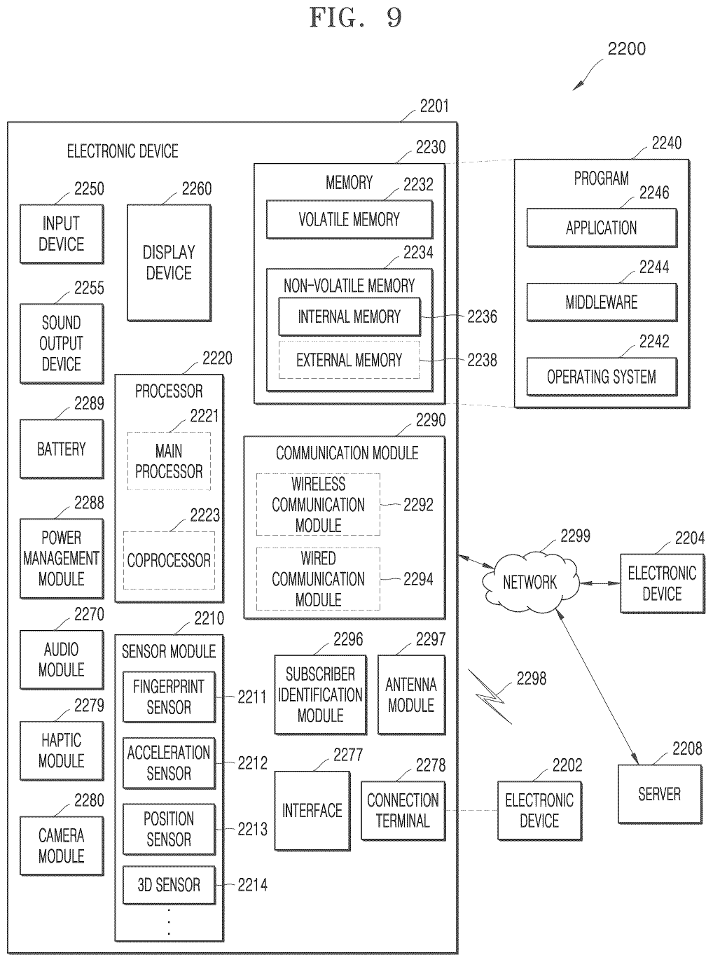

As an application example of the semiconductor devices, FIG. 9 schematically illustrates an electronic device 2201 according to an example embodiment.

Referring to FIG. 9, in a network environment 2200, the electronic device 2201 may communicate with another electronic device 2202 through a first network 2298 (such as a short-range wireless communication network) or may communicate with another electronic device 2204 and/or a server 2208 through a second network 2299 (such as a long-range wireless communication network). The electronic device 2201 may communicate with the electronic device 2204 through the server 2208. The electronic device 2201 may include a processor 2220, a memory 2230, an input device 2250, a sound output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297.

In an example, the semiconductor devices described with reference to FIGS. 1 to 6 may be included in at least one of the processor 2220, the memory 2230, the input device 2250, the sound output device 2255, the display device 2260, the audio module 2270, the sensor module 2210, the interface 2277, the haptic module 2279, the camera module 2280, the power management module 2288, the communication module 2290, the subscriber identification module 2296, or the antenna module 2297.

Some (the display device 2260 or the like) of the components of the electronic device 2201 may be omitted, or other components may be added to the electronic device 2201. Some of the components may be implemented as one integrated circuit. For example, components such as a fingerprint sensor 2211, an iris sensor, or an illumination sensor of the sensor module 2210 may be embedded in the display device 2260 (such as a display).

The processor 2220 may execute software (such as a program 2240) to control one or more other components (such as hardware or software components) of the electronic device 2201 which are connected to the processor 2220, and the processor 2220 may perform various data processing or operations. As part of data processing or computation, the processor 2220 may load commands and/or data received from other components (such as the sensor module 2210, the communication module 2290, or the like) on a volatile memory 2232, process the commands and/or data stored in the volatile memory 2232, and store resulting data in a non-volatile memory 2234. The processor 2220 may include: a main processor 2221 (such as a central processing unit, an application processor, or the like); and a coprocessor 2223 (such as a graphics processing unit, an image signal processor, a sensor hub processor, a communication processor, or the like) that may be operated independently or in conjunction with the main processor 2221. The coprocessor 2223 may consume less power than the main processor 2221 and may perform a specialized function.

The coprocessor 2223 may control functions and/or states related to some of the components (such as the display device 2260, the sensor module 2210, and the communication module 2290) of the electronic device 2201, instead of the main processor 2221 while the main processor 2221 is in an inactive state (sleep mode) or together with the main processor 2221 while the main processor 2221 is in an active state (application-execution mode). The coprocessor 2223 (such as an image signal processor, a communication processor, or the like or the like) may be implemented as part of a functionally related component (such as the camera module 2280 or the communication module 2290).

The memory 2230 may store various pieces of data desired by the components (such as the processor 2220, the sensor module 2210 or the like) of the electronic device 2201. For example, the data may include software (such as the program 2240) and instruction input data and/or output data which are related to the software. The memory 2230 may include the volatile memory 2232 and/or the non-volatile memory 2234. The non-volatile memory 2234 may include an internal memory 2236 and an external memory 2238. The program 2240 may be stored as software in the memory 2230 and may include an operating system 2242, middleware 2244, and/or an application 2246.

The input device 2250 may receive, from outside the electronic device 2201 (for example, a user), commands and/or data to be used in the components (such as the processor 2220) of the electronic device 2201. The input device 2250 may include a microphone, a mouse, a keyboard, and/or a digital pen (such as a stylus pen).

The sound output device 2255 may output a sound signal to the outside of the electronic device 2201. The sound output device 2255 may include a speaker and/or a receiver. The speaker may be used for general purposes such as multimedia playback or recorded data playback, and the receiver may be used to receive incoming calls. The receiver may be integrated as a part of the speaker or may be implemented as an independent separate device.

The display device 2260 may provide information to the outside of the electronic device 2201 in a visual manner. The display device 2260 may include a device such as a display, a hologram device, or a projector, and a control circuit for controlling the device. The display device 2260 may include touch circuitry configured to detect touches and/or a sensor circuit (such as a pressure sensor) configured to measure the magnitudes of forces generated by touches.

The audio module 2270 may convert a sound into an electric signal or may conversely convert an electric signal into a sound. The audio module 2270 may acquire a sound through the input device 2250, or may output a sound through the sound output device 2255 and/or the speaker and/or headphone of another electronic device (such as the electronic device 2202) which are directly or wirelessly connected to the electronic device 2201.

The sensor module 2210 may detect an operating state (such as the power or the temperature) of the electronic device 2201 or an external environmental state (such as a user state) and may generate an electrical signal and/or a data value corresponding to the detected state. The sensor module 2210 may include a sensor such as the fingerprint sensor 2211, an acceleration sensor 2212, a position sensor 2213, or a three-dimensional (3D) sensor 2214. In addition, the sensor module 2210 may further include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illumination sensor.

The 3D sensor 2214 may sense the shape and movement of an object by emitting light to the object and analyzing light reflected from the object. The 3D sensor 2214 may include a meta-optical device.

The interface 2277 may support one or more designated protocols that may be used by the electronic device 2201 for direct or wirelessly connection with another electronic device (such as the electronic device 2202). The interface 2277 may include a high-definition multimedia Interface (HDMI), a universal serial bus (USB) interface, a secure digital (SD) card interface, and/or an audio interface.

A connection terminal 2278 may include a connector through which the electronic device 2201 may be physically connected to another electronic device (such as the electronic device 2202). The connection terminal 2278 may include an HDMI connector, an USB connector, an SD card connector, and/or an audio connector (such as a headphone connector).

The haptic module 2279 may convert an electrical signal into a mechanical stimulus (such as vibration, movement, or the like) or an electrical stimulus that a user may perceive by the tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly of the camera module 2280 may collect light coming from a subject to be imaged. In an example, the camera module 2280 may capture at least one of a visible-light image or an IR image of the subject. In an example, the image signal processors included in the camera module 2280 may convert a captured IR image into a visible-light image and superimposing the captured IR image on the visible-light image.

The power management module 2288 may manage power supplied to the electronic device 2201. The power management module 2288 may be implemented as part of a power management integrated circuit (PMIC).

The battery 2289 may supply power to the components of the electronic device 2201. The battery 2289 may include non-rechargeable primary cells, rechargeable secondary cells, and/or fuel cells.

The communication module 2290 may support the establishment of a direct (wired) communication channel and/or a wireless communication channel between the electronic device 2201 and another electronic device (such as the electronic device 2202, the electronic device 2204, or the server 2208), and may support communication through the established communication channel. The communication module 2290 may include one or more communication processors that operate independently of the processor 2220 (such as an application processor) and support direct communication and/or wireless communication. The communication module 2290 may include a wireless communication module 2292 (such as a cellular communication module, a short-range wireless communication module, or a global navigation satellite system (GNSS) communication module) and/or a wired communication module 2294 (such as a local area network (LAN) communication module or a power line communication module). The communication modules 2222 and 2294 may communicate with another electronic device through the first network 2298 (for example, a short-range communication network such as Bluetooth, Wi-Fi direct, or infrared data association (IrDA)), or the second network 2299 (for example, a long-range communication network such as a cellular network, the Internet, or a computer network (LAN, WAN, or the like)). Such various types of communication modules may be integrated into one component (single chip, or the like) or may be implemented as a plurality of components (plural chips) separate from each other. The wireless communication module 2292 may identify and authenticate the electronic device 2201 in a communication network such as the first network 2298 and/or the second network 2299 by using subscriber information (such as an international mobile subscriber identifier (IMSI)) stored in the subscriber identification module 2296.

The antenna module 2297 may transmit or receive signals and/or power to or from the outside (for example, other electronic devices). An antenna may include a radiator which has a conductive pattern formed on a substrate (such as a PCB). The antenna module 2297 may include one or a plurality of such antennas. When the antenna module 2297 include a plurality of antennas, the communication module 2290 may select one of the plurality of antennas which is suitable for a communication method used in a communication network such as the first network 2298 and/or the second network 2299. Signals and/or power may be transmitted between the communication module 2290 and another electronic device through the selected antenna. In addition to the antennas, other components (such as a radio-frequency integrated circuit (RFIC)) may be included as part of the antenna module 2297.

Some of the components may be connected to each other and exchange signals (such as commands or data) by an inter-peripheral communication scheme (such as a bus, general purpose input and output (GPIO), serial peripheral interface (SPI), or mobile industry processor interface (MIPI)).

Commands or data may be transmitted between the electronic device 2201 and the (external) electronic device 2204 through the server 2208 connected to the second network 2299. The other electronic devices 2202 and 2204 and the electronic device 2201 may be the same type of electronic device or may be different types of electronic devices. All or some of operations of the electronic device 2201 may be executed in one or more of the other electronic devices 2202 and 2204, and the server 2208. For example, when the electronic device 2201 needs to perform a certain function or service, the electronic device 2201 may request one or more other electronic devices to perform a part or all of the function or service instead of performing the function or service by itself. The one or more other electronic devices receiving the request may perform an additional function or service related to the request, and may transmit results thereof to the electronic device 2201. To this end, cloud computing, distributed computing, and/or client-server computing techniques may be used.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

As described above, according to the one or more of the above example embodiments, in the semiconductor device including vertically stacked semiconductor elements, a semiconductor element formed in an FEOL process and a semiconductor element formed thereon in a BEOL process may be electrically connected to each other through a vertical downward internal via structure. That is, a lower surface of the semiconductor element formed in the BEOL process and an upper surface of the semiconductor element formed in the FEOL process may be connected to each other through a via hole that vertically penetrates an interlayer insulating layer formed therebetween.

Because the semiconductor element formed in the BEOL process and the semiconductor element formed in the FEOL process are directly connected to each other in a vertical direction as described above, an electrical connection path may be shorter than an electrical connection path of the related art, and thus, electrical resistance may be reduced. This indicates that current may be increased compared to the related art, and the operational power of the semiconductor device may be decreased compared to the related art. In addition, a decrease in electrical resistance may have an effect of decreasing RC delay (e.g., RC time constant), thereby increasing the operating speed of the semiconductor device.

In addition, when the semiconductor element formed in the BEOL process and the semiconductor element formed in the FEOL process are directly connected to each other in the vertical direction, a layer structure for electrically connecting the two semiconductor elements may be limited to a region between the two semiconductor devices, and thus, the size of the semiconductor device may be reduced, thereby increasing the degree of integration of the semiconductor device.

In addition, when the semiconductor element formed in the BEOL process and the semiconductor element formed in the FEOL process are directly connected to each other in the vertical direction, the number of layers and the number of processes that are required to electrically connect the two semiconductor elements to each other may be reduced.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising vertically stacked semiconductor elements, the semiconductor device comprising:
a first semiconductor layer;
a second semiconductor layer; and
an interlayer insulating layer between the first semiconductor layer and the second semiconductor layer, the interlayer insulating layer comprising an internal via structure connecting the first semiconductor layer and the second semiconductor layer to each other,
wherein the internal via structure comprises a layer structure through which an upper surface of a first material layer and a lower surface of a second material layer are connected to each other,
wherein the first material layer is included in one of the first semiconductor layer and the second semiconductor layer that is the interlayer insulating layer, and the second material layer is included in the other one of the first semiconductor layer and the second semiconductor layer that is above the interlayer insulating layer.

2. The semiconductor device of claim 1, wherein the layer structure comprises:
a first conductive layer in contact with the upper surface of the first material layer;
a second conductive layer comprising an upper surface that is in contact with a first region of the lower surface of the second material layer; and
a first interlayer conductive layer between the first conductive layer and the second conductive layer, the first interlayer conductive layer connecting the first conductive layer and the second conductive layer to each other.

3. The semiconductor device of claim 2, wherein the interlayer insulating layer comprises,
a first interlayer insulating layer covering the first material layer and having the first interlayer conductive layer thereon, and
a second interlayer insulating layer covering the first interlayer conductive layer and being on the first interlayer insulating layer,
wherein the first interlayer insulating layer comprises a first via hole exposing the upper surface of the first material layer therethrough and covered with the first interlayer conductive layer, and the first via hole is filled with the first conductive layer, and
wherein the second interlayer insulating layer comprises a second via hole exposing first interlayer conductive layer therethrough and covered with the first region of the lower surface of the second material layer, and the second via hole is filled with the second conductive layer.

4. The semiconductor device of claim 2, further comprising:
a second interlayer conductive layer being apart from the first interlayer conductive layer and having a same height e as the first interlayer conductive layer; and
a third conductive layer between the second interlayer conductive layer and a second region of the lower surface of the second material layer,
wherein the first region and the second region are apart from each other.

5. The semiconductor device of claim 4, wherein the third conductive layer is apart from the second interlayer conductive layer.

6. The semiconductor device of claim 1, wherein the second material layer comprises a two-dimensional channel layer.

7. The semiconductor device of claim 6, wherein the two-dimensional channel layer comprises:
a source region and a drain region that are apart from each other; and
a gate stack on the two-dimensional channel layer between the source region and the drain region.

8. The semiconductor device of claim 7, wherein the layer structure comprises a conductive layer connecting a lower surface of the source region and an upper surface of the first material layer to each other.

9. The semiconductor device of claim 8, further comprising:
a first electrode layer between the lower surface of the source region and the conductive layer and in contact with the lower surface of the source region and the conductive layer.

10. The semiconductor device of claim 9, wherein the first electrode layer is wider than the conductive layer and entirely covers an upper surface of the conductive layer.

11. The semiconductor device of claim 9, wherein the first electrode layer has a width substantially equal to a width of the conductive layer and entirely covers an upper surface of the conductive layer.

12. The semiconductor device of claim 11, wherein a portion of the conductive layer and the first electrode layer are surrounded by the interlayer insulating layer.

13. The semiconductor device of claim 8, wherein the conductive layer comprises two portions having different widths.

14. The semiconductor device of claim 1, wherein at least one of the first semiconductor layer or the second semiconductor layer comprises a transistor.

15. The semiconductor device of claim 14, wherein
the first semiconductor layer comprises a memory, and
the second semiconductor layer comprises a transistor comprising a two-dimensional channel layer.

16. The semiconductor device of claim 6, wherein the two-dimensional channel layer comprises one of an n-type two-dimensional semiconductor material and a p-type two-dimensional semiconductor material.

17. A method of manufacturing a semiconductor device comprising vertically stacked semiconductor elements, the method comprising:
forming a first semiconductor element on a substrate;
forming a first interlayer insulating layer covering the first semiconductor element;
forming a first via hole in the first interlayer insulating layer such that a portion of the first semiconductor element is exposed through the first via hole;
filling the first via hole with a first conductive plug;
forming a conductive layer on the first interlayer insulating layer to cover the first via hole and the first conductive plug;
forming a second interlayer insulating layer on the first interlayer insulating layer to cover the conductive layer;
forming a second via hole in the second interlayer insulating layer such that the conductive layer is exposed through the second via hole;
filling the second via hole with a second conductive plug;
forming a two-dimensional material layer on the second interlayer insulating layer to cover the second conductive plug; and
forming a gate stack on a portion of the two-dimensional material layer,
wherein the second conductive plug is in contact with a lower surface of the two-dimensional material layer.

18. The method of claim 17, wherein the forming of the two-dimensional material layer comprises:
separately forming the two-dimensional material layer outside the second interlayer insulating layer; and
transferring the separately-formed two-dimensional material layer onto the second interlayer insulating layer.

19. The method of claim 17, further comprising:
forming an electrode layer between the second conductive plug and the two-dimensional material layer.

20. An electronic device comprising the semiconductor device of claim 1.
